(19) United States
(12) Patent Application Publication
(10) Pub. No.: US 2003/0052087 A1
(43) Pub. Date: Mar. 20, 2003

(54) Plasma generating apparatus and SiO2 thin film etching method using the same

(75) Inventors: Gi-Chung Kwon, Kwangju (KR); Hong-Sik Byun, Sungnam (KR); Hong-Seub Kim, Yongin (KR); Joung-Sik Kim, Choongchungnam-Do (KR); Seong-Hyuk Choi, Seoul (KR); Hong-Young Chang, Daejeon (KR); Keun-Hei Bai, Daejeon (KR)

Correspondence Address: OSTROLENK FABER GERB & SOFFEN, 1180 AVENUE OF THE AMERICAS, NEW YORK, NY, 100368403

(73) Assignee: Jusung Engineering Co.

(21) Appl. No.: 10/235,606

(22) Filed: Sep. 4, 2002

(30) Foreign Application Priority Data
Sep. 18, 2001 (KR) 57520/2001

(51) Int. Cl. C23F 1/00; H01L 21/306; C23C 16/00; C03C 15/00

(52) U.S. Cl. 216/63; 118/723 E; 118/723 R; 118/723 I; 156/345.43; 156/345.48; 216/64

(57) ABSTRACT

In a plasma generating apparatus including a reaction chamber for providing a reaction space cut off from the outside; a plasma electrode installed at the outer upper portion of the reaction chamber, receiving high frequency power from the outside and generating plasma inside the reaction chamber; a grid horizontally installed to the reaction space, dividing the reaction space into an upper plasma generating space and a lower processing space and having plural through holes connecting the upper and lower spaces; an upper gas injector for providing gas to the plasma generating space; a lower gas injector for providing gas to the processing space; and a substrate supporting board installed to the processing space to be horizontally mounted with a substrate, by installing the grid in the reaction space, injecting inert gas through the upper gas injector and injecting process gas such as CxFy, etc. through the lower gas injector, a selective etching ratio of SiO₂ can be improved.

### BACKGROUND OF THE INVENTION

1. Field of the Invention

The present invention relates to a plasma generating apparatus, and in particular to a plasma generating apparatus which is capable of adequately adjusting an electron temperature of plasma by using a grid. In addition, the present invention relates to a SiO₂ thin film etching method which is capable of selectively etching a SiO₂ thin film by using the plasma generating apparatus.

2. Description of the Prior Art

In fabrication of a ULSI grade semiconductor device, SiO₂ etching technique is very important in forming contact holes. Herein, SiO₂ has to be etched as anisotropy. And, highly selective etching ratio is required in SiO₂/PR (photoresist) and SiO₂/Si, etc.

In general, in etching of SiO₂, a CCP (capacitively coupled plasma) is largely used. In more detail, to get a high etching rate, an ECR (electron cyclotron resonance), a helicon and an ICP (inductively coupled plasma), etc. are used. In use of the ICP, it is possible to get a high etching rate with a very simple structure, and accordingly the ICP is being watched with keen interest.

Generally, fluorocarbon gases (CxFy) are used in SiO₂ etching. In use of fluorocarbon plasma, because fluoropolymer is accumulated onto a Si surface, Si is slowly etched and SiO₂ is relatively quickly etched, and accordingly a selective etching ratio of SiO₂/Si increases.

As described above, in use of fluorocarbon gases, a ratio of CxFy/F greatly influences selective etching of SiO₂. In more detail, the smaller the CxFy/F ratio, the more F content of plasma increases, and accordingly the more fluoropolymer can be formed. Therefore, selective etching of SiO₂ can be performed well. However, when the ratio CxFy/F is too small, because a quantity of CxFy is relatively small, etching rate of SiO₂ gets slower, and accordingly a selective etching ratio of SiO₂/Si is reduced.

In particular, because the ICP (inductively coupled plasma) has a higher CxFy dissociation rate (CF₂+e□CF+F+e) than that of the CCP (capacitively coupled plasma), in apply of the ICP, because F atom is excessively generated, a quantity of CxFy is comparatively decreased, and accordingly selective etching ratio of SiO₂/Si is reduced.

The high dissociation rate of CxFy is greatly influenced by a high electron temperature of plasma. Y. Hikosaka reports although an electron temperature minutely rises, a dissociation rate of CF2 is greatly increased (reference: Y. Hikosaka, M. Nakamura and H. Sugai, Jpn. J. AppI. Phys. 33, 2157, 1994). Accordingly, in order to get a high SiO₂ selective etching ratio, an electron temperature of plasma has to be lowered.

### SUMMARY OF THE INVENTION

In order to solve the above-mentioned problem, it is an object of the present invention to provide a plasma generating apparatus which is capable of lowering an electron temperature of plasma.

In addition, it is another object of the present invention to provide a SiO₂ thin film etching method which is capable of selectively etching a SiO₂ thin film by using the above-mentioned plasma generating apparatus.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 illustrates a plasma generating apparatus in accordance with the present invention; and

FIGS. 2a and 2b respectively illustrate a shape of a grid.

### DETAILED DESCRIPTION OF THE PREFERRED EMBODIMENT

In order to achieve the object of the present invention, a plasma generating apparatus in accordance with the present invention includes a reaction chamber for providing a reaction space cut off from the outside; a plasma electrode installed at the outer upper portion of the reaction chamber, receiving high frequency power from the outside and generating plasma inside the reaction chamber; a grid horizontally installed to the reaction space, dividing the reaction space into an upper plasma generating space and a lower processing space and having plural through holes connecting the upper and lower spaces; an upper gas injector for providing gas to the plasma generating space; a lower gas injector for providing gas to the processing space; and a substrate supporting board installed to the processing space to be horizontally mounted with a substrate.

Herein, a coil antenna such as a parallel resonance coil antenna can be used as the plasma electrode. And, the grid is made of dielectric or metal such as Si, Al₂O₃, SiC or AIN, etc., it is preferable for the grid to have a thickness in the range of 10÷m˜5 mm. It is preferable for the through hole of the grid to have a size in the range of 10 mesh˜500 mesh per inch. Inert gas is injected through the upper gas injector, process gas such as CxFy, CH₂F₂, CO or O₂, etc. is injected through the lower gas injector.

In order to achieve the another object of the present invention, in the plasma generating apparatus in accordance with the present invention, a SiO₂ thin film etching method in accordance with the present invention includes injecting inert gas through the upper gas injector; injecting CxFy, CH₂F₂, CO or O₂ gas through the lower gas injector; applying high frequency power having a frequency in the range of 13.56 MHz˜300 MHz to the plasma electrode; and etching a SiO₂ thin film formed onto the substrate. According to circumstances, high frequency power having a frequency in the range of 2 MHz˜13.56 MHz can be applied to the substrate supporting board.

Hereinafter, the preferred embodiment of the present invention will be described in detail with reference to accompanying drawings.

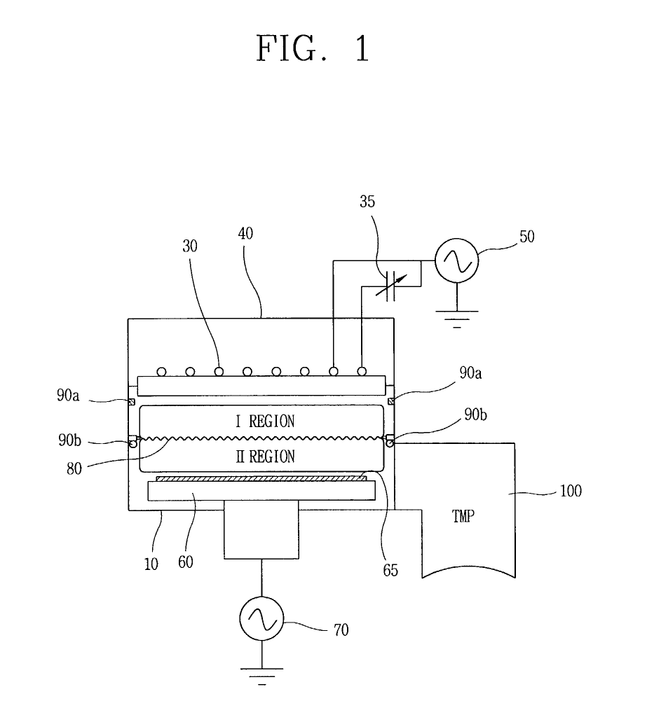

FIG. 1 illustrates a plasma processing apparatus in accordance with the present invention.

In a reaction chamber 10 for providing a reaction space cut off from the outside, a ceramic plate 20 is placed onto the upper portion of the reaction chamber 10, a parallel resonance coil antenna 30 is placed onto the upper surface of the ceramic plate 20. The parallel resonance coil antenna 30 receives high frequency power having a frequency in the range of 13.56 MHz˜300 MHz from external high frequency power 50. A resonance capacitor 35 for resonance is connectedly installed at the parallel resonance coil antenna 30. An impedence matching box is installed between the external high frequency power 50 and the parallel resonance coil antenna 30.

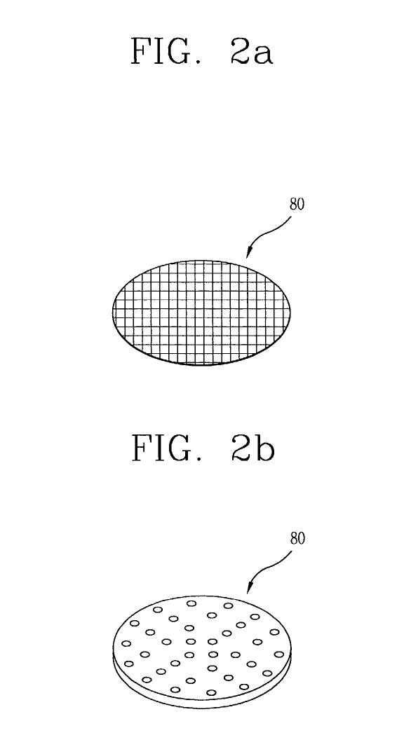

In the reaction space, a grid 80 having a thickness in the range of 10 μm˜5 mm is horizontally installed in order to divide the reaction space into an upper plasma generating space (I region) and a lower processing space (II region). As depicted in FIGS. 2a and 2b, plural through holes for connecting the plasma generating space (I region) with the processing space (II region) are formed on the grid 80.

As depicted in FIG. 2a, the through hole can have a mesh shape, or as depicted in FIG. 2b, plural through holes can be formed. It is preferable for the through holes to be formed in the range of 10˜500 (the number of the through holes) per inch. The grid 80 can be made of dielectric such as Si, Al₂O₃, SiC or AIN, etc.

The upper gas injector 90a is installed in the plasma generating space (I region), and the lower gas injector 90b is installed in the processing space (II region). The substrate supporting board 60 on which the substrate 65 is horizontally installed is installed in the processing space (II region). The substrate supporting board 60 receives high frequency power having a frequency in the range of 2 MHz˜13.56 MHz from the external high frequency power 70. Inert gas is injected through the upper gas injector 90a, and process gas such as CxFy, CH₂F₂, CO or O₂, etc. is injected through the lower gas injector 90b. Gases injected through the gas injectors 90a, 90b are discharged to the outside through the TMP (turbo-molecular pump) 100.

Etching SiO₂ by using the plasma generating apparatus in accordance with the present invention will be described.

As an example of injecting inert gas, when Ar gas is injected through the upper gas injector 90a and high frequency power is applied to the parallel resonance coil antenna 30, ICP Ar plasma is generated in the plasma generating space (I region). The grid 80 has a floating potential by the Ar plasma, in comparison with the Ar plasma, the grid 80 relatively has a negative potential. Accordingly, only potential having higher kinetic energy than the potential of the grid 80 moves from the plasma generating space (I region) to the processing space (II region) through the grid 80.

The process gas CxFy provided to the processing space (II region) through the lower gas injector 90b is dissociated mainly by electrons moved from the plasma generating space (I region) to the processing space (II region) and turns into plasma. Herein, the electrons lose their energy by inelastic collision with the CxFy gas. Accordingly, an electron temperature in the processing space (II region) is lower than that of the plasma generating space (I region). According to circumstances, high frequency power can be also applied to the substrate supporting board 60.

Because the electron temperature in the processing space (II region) is low, a dissociation rate of the CxFy is low, and accordingly a selective etching ratio of SiO₂/PR, SiO₂/Si, etc. is improved. It is possible to have the same effect by put the grid 80 to earth.

As described above, in the plasma generating apparatus in accordance with the present invention and the SiO₂ thin film etching method using the same, by installing the grid 80 in the reaction space, injecting inert gas through the upper gas injector 90a and injecting process gas such as CxFy, etc. through the lower gas injector 90b, a selective etching ratio of SiO₂ can be improved.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

What is claimed is:

1. A plasma generating apparatus, comprising:
a reaction chamber for providing a reaction space cut off from the outside;
a plasma electrode installed at the outer upper portion of the reaction chamber, receiving high frequency power from the outside and generating plasma inside the reaction chamber;
a grid horizontally installed to the reaction space, dividing the reaction space into an upper plasma generating space and a lower processing space and having plural through holes connecting the upper and lower spaces;
an upper gas injector for providing gas to the plasma generating space;
a lower gas injector for providing gas to the processing space; and
a substrate supporting board installed to the processing space to be horizontally mounted with a substrate.

2. The apparatus of claim 1, wherein the plasma electrode is a coil antenna.

3. The apparatus of claim 2, wherein the coil antenna is a parallel resonance coil antenna.

4. The apparatus of claim 3, wherein high frequency power applied to the coil antenna has a frequency in the range of 13.56 MHz˜300 MHz.

5. The apparatus of claim 1, wherein the substrate supporting board receives high frequency power having a frequency in the range of 2 MHz˜13.56 MHz.

6. The apparatus of claim 1, wherein the grid is made of dielectric or metal.

7. The apparatus of claim 6, wherein the dielectric is one of Si, Al₂O₃, SiC or AIN.

8. The apparatus of claim 1, wherein the grid has a thickness in the range of 10 μm˜5 mm.

9. The apparatus of claim 1, wherein the through hole of the grid has a size in the range of 10 mesh˜500 mesh per inch.

10. The apparatus of claim 1, wherein the grid is put to earth.

11. The apparatus of claim 1, wherein inert gas is injected through the upper gas injector, and process gas is injected through the lower gas injector.

12. The apparatus of claim 11, wherein the process gas is one of CxFy, CH₂F₂, CO or O₂.

13. In the plasma generating apparatus of claim 1, a SiO₂ thin film etching method, comprising:
injecting inert gas through the upper gas injector;
injecting one of CxFy, CH₂F₂, CO or O₂ gas through the lower gas injector;
applying high frequency power having a frequency in the range of 13.56 MHz˜300 MHz to the plasma electrode; and
etching a SiO₂ thin film formed onto the substrate.

14. The method of claim 13, wherein high frequency power having a frequency in the range of 2 MHz˜13.56 MHz is applied to the substrate supporting board.
